(19) United States
(12) Patent Application Publication
(10) Pub. No.: US 2010/0102369 A1
(43) Pub. Date: Apr. 29, 2010

(54) FERROELECTRIC MEMORY WITH MAGNETOELECTRIC ELEMENT

(75) Inventors: Wei Tian, Bloomington, MN (US); Haiwen Xi, Prior Lake, MN (US); Yuankai Zheng, Bloomington, MN (US); Venugopalan Vaithyanathan, Bloomington, MN (US); Insik Jin, Eagan, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/420,131

(22) Filed: Apr. 8, 2009

Related U.S. Application Data
(60) Provisional application No. 61/109,197, filed on Oct. 29, 2008.

(51) Int. Cl. H01L 29/82; H01L 29/68

(52) U.S. Cl. 257/295; 257/421; 257/E29.323; 257/E29.17

(57) ABSTRACT

A ferroelectric memory cell that has a magnetoelectric element between a first electrode and a second electrode, the magnetoelectric element comprising a ferromagnetic material layer and a multiferroic material layer with an interface therebetween. The magnetization orientation of the ferromagnetic material layer and the multiferroic material layer may be in-plane or out-of-plane. FeRAM memory devices are also provided.

### RELATED APPLICATION

This application claims priority to U.S. provisional patent application No. 61/109,197, filed on Oct. 29, 2008 and titled “Ferroelectric Random Access Memory Using Magnetoelectric Element”. The entire disclosure of application No. 61/109,197 is incorporated herein by reference.

### BACKGROUND

Flash memory, a memory cell that utilizes a floating gate for data storage, is common in today's electronic world. It is generally difficult, however, to scale down the floating gate of NAND flash memories below 30 nm due to the interference with adjacent memory cells. Charge-trap memories such as MONOS have short data retention problems. Current-driven resistive switching memories such as MRAM and RRAM or ReRAM are unscalable below about 20 nm because of the significant IR drop of the bit line.

FeFETs have been proposed for NAND flash memory, or, for ferroelectric random access memory (FeRAM). FeRAM devices are memory devices using the orientation of an electric dipole induced by a high-frequency alternating current (AC) field. FeRAM devices have a capacitor made of a ferroelectric substance where two poles, established by applying an electric field, remain even when the electric field is cut off. Generally, ferroelectric substances are, for example, Pb(ZrₓTi₁₋ₓ)O₃ (PZT) and SrBi₂Ta₂O₉ (SBT). FeRAM stores binary data in a nonvolatile state based on the magnitudes of two different polarization modes. It is desired to make a more stable FeRAM device, to improve its accuracy and storage.

### BRIEF SUMMARY

The present disclosure relates to ferroelectric random access memory (FeRAM) that includes a magnetoelectric element.

One particular embodiment of this disclosure is to a ferroelectric memory cell that has a magnetoelectric element between a first electrode and a second electrode, the magnetoelectric element comprising a ferromagnetic material layer and a multiferroic material layer with an interface therebetween.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1 is a schematic diagram of an illustrative memory unit including a memory element and a semiconductor transistor;

FIG. 2 is a circuit diagram of an illustrative memory unit;

FIGS. 3A and 3B are schematic diagrams of an illustrative magnetoelectric element as affected by an electric field;

FIG. 4 is a schematic diagram of a first embodiment of a memory cell with a magnetoelectric element;

FIG. 5 is a schematic diagram of a second embodiment of a memory cell with a magnetoelectric element;

FIG. 6 is a schematic diagram of a third embodiment of a memory cell with a magnetoelectric element; and

FIG. 7 is a schematic diagram of a fourth embodiment of a memory cell with a magnetoelectric element.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

The ferroelectric random access memory (FeRAM) and magnetoelectric elements of this disclosure have a ferromagnetic metal layer coupled to a multiferroic layer. One benefit of utilizing such a multiple layer element is that the anisotropy of the ferromagnetic layer provides an additional energy barrier that thwarts the reverse and relaxation of the electric polarization of the multiferroic layer. In addition, the interface coupling between the ferromagnetic metal layer and the multiferroic layer stabilizes the ferroelectric domains in the multiferroic material. As a result, the electric polarization of the magnetoelectric element is more stable than for a single layer of multiferroic or ferroelectric material. A significant improvement upon the data retention of the FeRAM cells is, therefore, achieved.

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense. Any definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

The present disclosure relates to ferroelectric random access memory (FeRAM) that includes a magnetoelectric (ME) element. The magnetoelectric element has ferromagnetic and multiferroic layers as the storage element.

Magnetic cells and FeRAM that utilize magnetoelectric elements having a ferromagnetic metal layer coupled to a multiferroic layer have numerous benefits over elements having only a single layer of ferromagnetic material or multiferroic material. One benefit is that the anisotropy of the coupled ferromagnetic layer provides an additional energy barrier that inhibits the reversal of the electric polarization of the multiferroic layer. The interface coupling between the ferromagnetic metal layer and the multiferroic layer stabilizes the ferroelectric domains in the multiferroic material. As a result, the electric polarization of the magnetoelectric element is more stable than for a single layer of multiferroic or ferroelectric material. A significant improvement upon the data retention of the FeRAM cells is, therefore, achieved. Another benefit is improved data retention provided by the magnetoelectric element, due to the increased stability. This improved data retention leads to a third benefit, that of smaller element size, which can be obtained by utilizing multiferroic materials with large electric polarization. As a result, the memory density increases as well. While the present disclosure is not so limited, an appreciation of various aspects of the disclosure will be gained through a discussion of the examples provided below.

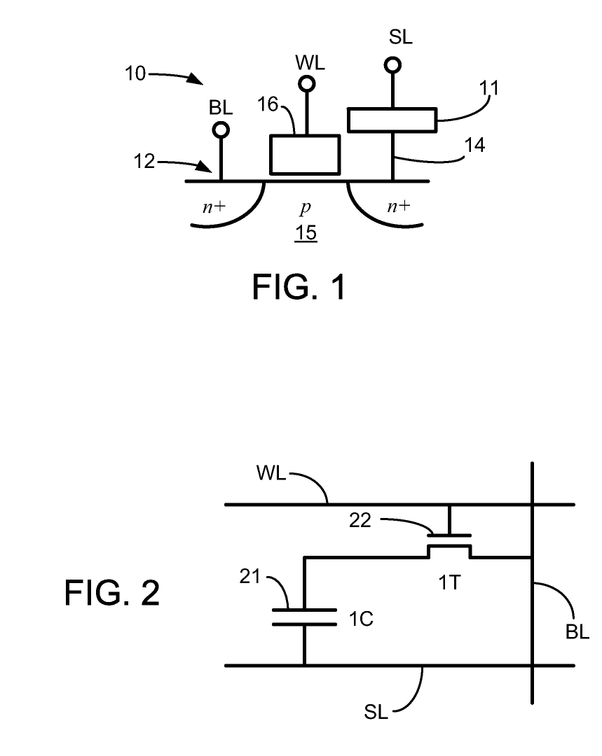

FIG. 1 is a cross-sectional schematic diagram of an illustrative ferroelectric memory unit 10 that includes a ferroelectric memory cell 11 electrically coupled to a semiconductor transistor 12 via an electrically conducting element 14. Source line SL is coupled to the opposite side of ferroelectric memory cell 11. Transistor 12 includes a semiconductor substrate 15 having a doped source region and a doped drain region (e.g., illustrated as n-doped regions) and a channel region (e.g., illustrated as a p-doped channel region) between the doped regions. Transistor 12 includes a gate 16 that is electrically coupled to a word line WL to allow selection and current to flow from a bit line BL to memory cell 11 via conducting element 14. An array of memory units 10 can be formed on a semiconductor substrate utilizing semiconductor fabrication techniques.

FIG. 2 is a circuit diagram of an illustrative ferroelectric memory unit. An FeRAM storage unit consists of one ferroelectric capacitor (1C) 21 and one transistor (1T) 22. Ferroelectric cell 11 of FIG. 1 is represented by ferroelectric capacitor 21 of FIG. 2 and gate 16 of FIG. 1 is represented by transistor 22.

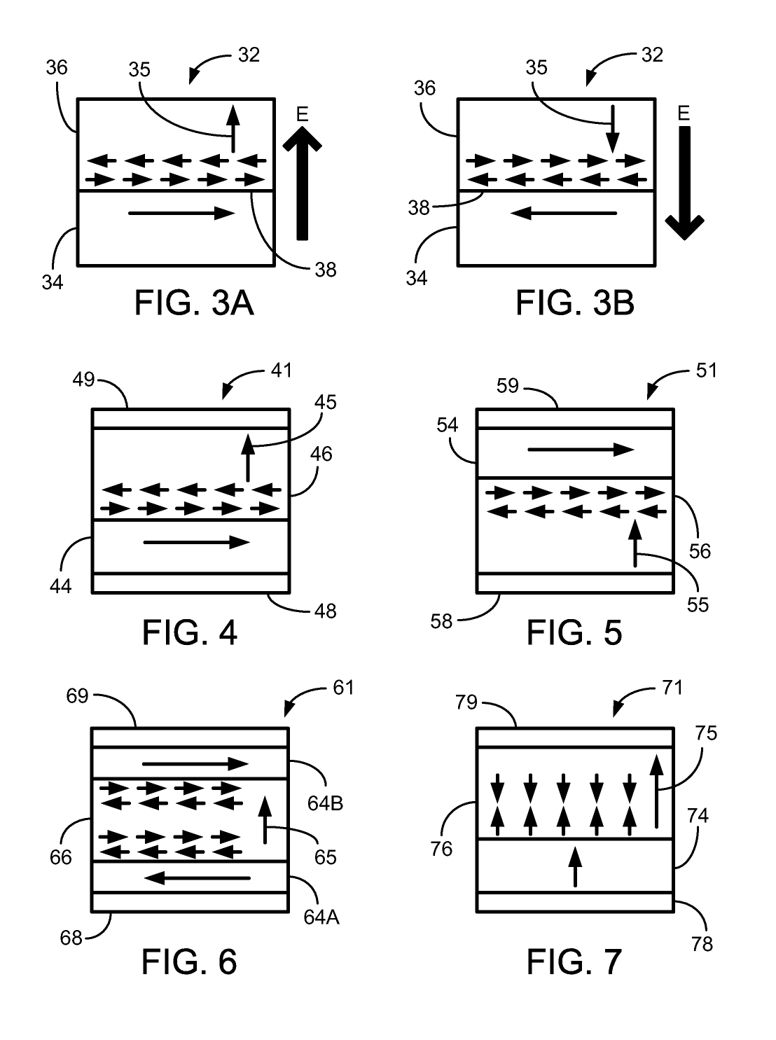

FIGS. 3A and 3B illustrate a ferroelectric memory element 32, specifically a magnetoelectric element, having a ferromagnetic layer and a multiferroic layer. Ferroelectric memory element 32 has a ferromagnetic layer 34 adjacent a multiferroic layer 36. In most embodiments, there is no intervening layer present between ferromagnetic layer 34 and multiferroic layer 36.

Ferromagnetic layer 34 is formed of ferromagnetic material that has a magnetization orientation. Examples of ferromagnetic materials include Fe, Co or Ni and alloys thereof, such as NiFe, CoFe, CoFeB, and CoFeNi. Ferromagnetic layer 34 may be either a single layer film or a multilayer film with ferromagnetic sublayers separated by nonmagnetic layers such as Ru, Cu, Al, Ag, and Au. In some embodiments, ferromagnetic layer 34 is from a few nanometers thick to a few tens of nanometers.

Multiferroic layer 36 is formed of a multiferroic material. A multiferroic material has both magnetic (could be either ferromagnetic or antiferromagnetic) and ferroelectric orders. A sole ferroelectric material does not have magnetic order but only electric polarization.

Useful multiferroic materials possess simultaneously the magnetic and electric orders together with a magneto-electric (ME) effect, which means coupling between electric and magnetic fields exists in the material and allows for additional degrees of freedom to control electric polarization by magnetic fields or to control magnetization by an electric field. Multiferroic materials can be single materials or composite materials that are made of ferroelectric (FE) material and ferromagnetic (FM) or antiferromagnetic (AFM) material, often present as domains or particles of one material present in a matrix of the other material. In many embodiments, multiferroic materials include Bi (e.g., Bi ferrite), Ni (e.g., Ni ferrite), Co (e.g., Co ferrite), Li (e.g., Li ferrite), Cu (e.g., Cu ferrite), Mn (e.g., Mn ferrite), or YIG (yttrium iron garnet), ferromagnetic material, and a ferroelectric material such as BaTiO₃, PZT (Pb(ZrₓTi₁₋ₓ)O₃), PMN (Pb(Mg, Nb)O₃), PTO (PbTiO₃), SBT (SrBi₂Ta₂O₉) or (Sr, Ba)Nb₂O₅. Examples of single multiferroic materials, which have both ferroelectric and magnetic properties, include BiFeO₃, YMnO₃, TbMnO3, and TbMn₂O₅. Examples of composite multiferroic materials include PZT/CoZnFe₂O₄, PZT/NiZnFe₂O₄, BaTiO₃/CoFe₂O₄, and others. Multiferroic layer 36 may be formed as thin layers (e.g., a few tens of nanometers) of different types of multiferroic material. In some embodiments, multiferroic layer 36 is from a few nanometers thick to a few tens of nanometers. In most embodiments, multiferroic layer 36 and ferromagnetic layer 34 will have the same or similar thickness, but in some embodiments, multiferroic layer 36 is slightly thicker (for example, a few nm thicker).

For magnetoelectric element 32, the magnetic orders of the multiferroic materials (such as BiFeO₃) of layer 36 are coupled to the magnetizations of the ferromagnetic metals (such as CoFe and NiFe) of layer 34. The magnetoelectric effect, e.g. the coupling of the ferroelectric polarization with the magnetic orders, of magnetoelectric element 32 enhances the stability of electric polarization in the multiferroic constituent (i.e., of layer 36) and thus improves the data retention of the resulting FeRAM by increasing the energy barrier needed to switch from one data state (e.g., “0”) to the other (e.g., “1”).

The coupling in multiferroic layer 36 between its ferroelectric polarization (identified as reference numeral 35) and its magnetic moments is quadratic, meaning the polarization orientation and the magnetic moment axis are perpendicular to each other. When multiferroic layer 36 is in atomic contact with ferromagnetic layer 34 (that is, they have an interface 38 therebetween), the interface exchange coupling, also referred to as the exchange bias effect, will give a coupling between the polarization of multiferroic layer 36 and the magnetization of ferromagnetic layer 34. FIGS. 3A and 3B show the polarization configuration and the magnetic moment configuration when multiferroic element 30 is poled by an external electric field E. The ferromagnetic magnetization can be switched by external electric field E. In FIG. 3A, electric field E points from ferromagnetic layer 34 to multiferroic layer 36, thus resulting in parallel ferroelectric polarization 35 and magnetization orientations in ferromagnetic layer 34 and multiferroic layer 36 as illustrated. In FIG. 3B, electric field E points opposite, from multiferroic layer 36 to ferromagnetic layer 34. The resulting ferroelectric polarization 35 and magnetization orientations in ferromagnetic layer 34 and multiferroic layer 36 are illustrated.

By having multiferroic layer 36 adjacent to ferromagnetic layer 34, the interface exchange coupling between the two layers increases the energy barrier needed to switch the magnetization orientation of ferromagnetic layer 34 from one direction to the other, or, from one data state to the other, thus, the resulting magnetoelectric element 32 is more stable than a ferroelectric element having only a ferromagnetic layer.

The previous discussion directed to magnetoelectric element 32 and layers 34, 36 of FIGS. 3A and 3B applies, as appropriate and in general, to the elements described below. The various features of the memory elements described below are similar to and have the same or similar properties and features as the corresponding features of element 32 described above, unless indicated otherwise.

FIGS. 4, 5, 6 and 7 show various FeRAM memory cell structures with multiferroic-ferromagnetic layers sandwiched by a top electrode and a bottom electrode.

In FIG. 4, a memory cell 41 has a ferromagnetic layer 44, a multiferroic layer 46, and first and second electrodes 48, 49. First electrode 48 is closest to the substrate (e.g., wafer) on which memory cell 41 is built. In this embodiment, ferromagnetic layer 44 is proximate first electrode 48 and multiferroic layer 46 is proximate second electrode 49, so that multiferroic layer 46 is above ferromagnetic layer 44 and is spaced farther from the substrate than ferromagnetic layer 44. The ferroelectric polarization of layer 46 is identified as reference numeral 45. Ferroelectric polarization 45 determines the magnetization orientation of multiferroic layer 46 which in turn sets the magnetization orientation of ferromagnetic layer 44. The interface exchange coupling between ferromagnetic layer 44 and multiferroic layer 46 increases the energy barrier needed to switch the magnetization orientation of ferromagnetic layer 44 from one direction to the other, or, from one data state to the other.

In FIG. 5, a memory cell 51 has a ferromagnetic layer 54, a multiferroic layer 56, and first and second electrodes 58, 59. First electrode 58 is closest to the substrate (e.g., wafer) on which memory cell 51 is built. In this embodiment, unlike memory cell 41 of FIG. 4, multiferroic layer 56 is proximate first electrode 58 and ferromagnetic layer 54 is proximate second electrode 59, so that ferromagnetic layer 54 is above multiferroic layer 56 and is spaced farther from the substrate than multiferroic layer 56. The ferroelectric polarization of layer 56 is identified as reference numeral 55. Ferroelectric polarization 55 determines the magnetization orientation of multiferroic layer 56 which in turn sets the magnetization orientation of ferromagnetic layer 54. The interface exchange coupling between ferromagnetic layer 54 and multiferroic layer 56 increases the energy barrier needed to switch the magnetization orientation of ferromagnetic layer 54 from one direction to the other, or, from one data state to the other.

The memory cell of FIG. 6 includes multiple layers of at least one of the ferromagnetic layer and the multiferroic layer. In the embodiment of FIG. 6, memory cell 61 has a first ferromagnetic layer 64A, a second ferromagnetic layer 64B, a multiferroic layer 66, and first and second electrodes 68, 69. In this embodiment, first ferromagnetic layer 64A is proximate first electrode 68 and second ferromagnetic layer 64B is proximate second electrode 69, with multiferroic layer 66 therebetween. The ferroelectric polarization of layer 66 is identified as reference numeral 65. Ferroelectric polarization 65 determines the magnetization orientation of multiferroic layer 66 which in turn sets the magnetization orientation of ferromagnetic layers 64A, 64B. The interface exchange coupling between ferromagnetic layer 64A and multiferroic layer 66 and also ferromagnetic layer 64B and multiferroic layer 66 increases the energy barrier needed to switch the magnetization orientation of each ferromagnetic layer 64A, 64B from one direction to the other, or, from one data state to the other. In some embodiments, because of the structure of multiferroic layer 66, the magnetization orientations of ferromagnetic layers 64A, 64B will be anti-parallel to each other. In other embodiments, the magnetization orientations of ferromagnetic layers 64A, 64B will be parallel to each other.

It is noted that the magnetoelectric elements are not limited to a bi-layer structure (e.g., memory cell 41 of FIG. 4 or memory cell 51 of FIG. 5) or a tri-layer structure (e.g., memory cell 61 of FIG. 6). Additional embodiments of memory cells may be multiple-layer structures composed of alternatively stacked ferromagnetic layers and multiferroic layers. For example, a multiple-layered structure may be made with a ferroelectric-ferromagnetic-multiferroic material coupled with an antiferromagnetic layer at an interface. The nature of the coupling of the multiferroic magnetization with the magnetization of the ferromagnetic metals will be one or more of ferromagnetic coupling, antiferromagnetic coupling, and exchange bias coupling.

The previous embodiments, the layers of the particular magnetic cells 41, 51, 61 have in-plane anisotropy and in-plane magnetization. This in-plane anisotropy of the magnetizations of the ferromagnetic layers 44, 54, 64A, 64B can be achieved by patterning the magnetoelectric cells with a certain aspect ratio (usually a length:width of about 2:1 and greater). The magnetization orientation of the multiferroic layers 46, 56, 66 will follow that of the corresponding ferromagnetic layers 44, 54, 64A, 64B.

FIG. 7 illustrates an embodiment of an FeRAM memory cell structure with multiferroic-ferromagnetic layers sandwiched by a top electrode and a bottom electrode, the multiferroic-ferromagnetic layers having an out-of-plane or perpendicular anisotropy and magnetization. For magnetic memory cells having out-of-plane or perpendicular magnetic anisotropy, a stronger coupling is experienced among the ferromagnetic layers than in magnetic stacks having in-plane magnetic anisotropy. The higher coupling results in a lower needed switching current (Ic).

In FIG. 7, a memory cell 71 has a ferromagnetic layer 74, a multiferroic layer 76, and first and second electrodes 78, 79. First electrode 78 is closest to the substrate (e.g., wafer) on which memory cell 71 is built. In this embodiment, ferromagnetic layer 74 with an out-of-plane or perpendicular magnetization is proximate first electrode 78 and multiferroic layer 76 is proximate second electrode 79, so that multiferroic layer 76 is above ferromagnetic layer 74 and is spaced farther from the substrate than ferromagnetic layer 74. The out-of-plane anisotropy of the magnetizations of the ferromagnetic layer 74 can be achieved, for example, by external magnetic fields applied during the formation (e.g., deposition) of ferromagnetic layer 74. Examples of ferromagnetic materials with perpendicular magnetization orientation include single layers of TbCoFe and GdCoFe and multiple layers of [Co/Pt]n. The magnetization orientation of the multiferroic layer 76 will follow that of ferromagnetic layer 74. The ferroelectric polarization of layer 76 is identified as reference numeral 75. For the instance of out-of-plane magnetization, ferroelectric polarization 75 is also out-of-plane. Ferroelectric polarization 75 determines the magnetization orientation of multiferroic layer 76 which in turn sets the magnetization orientation of ferromagnetic layer 74. Similar to the in-plane magnetization embodiments, the interface exchange coupling between ferromagnetic layer 74 and multiferroic layer 76 increases the energy barrier needed to switch the magnetization orientation of ferromagnetic layer 74 from one direction to the other, or, from one data state to the other.

In each of the embodiments of FIGS. 4-7, the ferromagnetic metal layer may serve as either the top or bottom electrode, eliminating the need for a separate electrode; for example, for the embodiment of FIG. 4, a separate first electrode 48 may be eliminated and ferromagnetic layer 44 may function as first electrode 48, whereas for the embodiment of FIG. 5, a separate second electrode 59 may be eliminated and ferromagnetic layer 54 may function as second electrode 59.

To write to magnetic cells 41, 51, 61, 71 an electric field pulse is applied in either a first direction (e.g., from the substrate, as in FIG. 3A) or an opposite, second direction (e.g., toward the substrate, as in FIG. 3B). The switching of the ferroelectric polarization (e.g., ferroelectric polarization 45, 55, 65, 75) from one direction to the other direction is completed by electric field pulse. As shown in FIGS. 3A and 3B, as the electric field pulse is reversed so is the in-plane magnetization of the ferromagnetic layer. The same is true for out-of-plane magnetization layers. A data bit state, either a “0” or “1”, is defined as the direction of a ferromagnetic layer orientation.

Any of the structures of this disclosure may be made by thin film techniques such as chemical vapor deposition (CVD), physical vapor deposition (PVD), and atomic layer deposition (ALD).

Thus, embodiments of the FERROELECTRIC MEMORY WITH MAGNETOELECTRIC ELEMENT are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present invention is limited only by the claims that follow.

What is claimed is:

1. A ferroelectric memory cell comprising:
a first electrically conducting electrode;
a second electrically conducting electrode; and
a magnetoelectric element between the first electrode and the second electrode, the magnetoelectric element comprising a ferromagnetic material layer and a multiferroic material layer with an interface therebetween.

2. The memory cell of claim 1 wherein the ferromagnetic material layer includes at least one of Fe, Co or Ni, or alloys thereof.

3. The memory cell of claim 1 wherein the multiferroic material layer includes at least one of BaTiO₃, Pb(ZrTi)O₃, PbMgO₃, PbNbO₃, PbTiO₃, SrNb₂O₅, BaNb₂O₅, BiFeO₃, YMnO₃, TbMnO3, and TbMn₂O₅.

4. The memory cell of claim 3 wherein the multiferroic material layer comprises a matrix of one of BaTiO₃, Pb(ZrTi)O₃, PbMgO₃, PbNbO₃, PbTiO₃, SrNb₂O₅, BaNb₂O₅, BiFeO₃, YMnO₃, TbMnO3, and TbMn₂O₅ and domains of one of CoZnFe₂O₄, NiZnFe₂O₄, and CoFe₂O₄.

5. The memory cell of claim 3 wherein the multiferroic layer comprises a single layer of material.

6. The memory cell of claim 3 wherein the multiferroic layer comprises alternating layers of two materials.

7. The memory cell of claim 1 wherein the first electrode is proximate a substrate on which the memory cell is made, and the multiferroic layer is adjacent the first electrode.

8. The memory cell of claim 1 wherein the first electrode is proximate a substrate on which the memory cell is made, and the ferromagnetic layer is adjacent the first electrode.

9. The memory cell of claim 1 wherein the ferromagnetic layer has an in-plane magnetization orientation and the multiferroic layer has an in-plane magnetization orientation.

10. The memory cell of claim 1 wherein the ferromagnetic layer has an out-of-plane magnetization orientation and the multiferroic layer has an out-of-plane magnetization orientation.

11. The memory cell of claim 1 wherein the magnetoelectric element further comprises a second ferromagnetic layer, with the multiferroic material layer between the ferromagnetic layer and the second ferromagnetic layer.

12. An FeRAM memory device comprising:
a substrate having a source region and a drain region with a channel region therebetween;
a gate electrically between the channel region and a word line;
a magnetoelectric memory cell electrically connected to one of the source region and the drain region, the magnetoelectric cell comprising a ferromagnetic material layer and a multiferroic material layer with an interface therebetween;
a first line electrically connected to the magnetoelectric memory cell; and
a second line electrically connected to the other of the source region and the drain region.

13. The memory device of claim 12 wherein the magnetoelectric cell is electrically connected to the source region and the first line is a source line, and the second line is a bit line connected to the drain region.

14. The memory device of claim 12 wherein the ferromagnetic material layer includes at least one of Fe, Co or Ni, or alloys thereof.

15. The memory device of claim 12 wherein the multiferroic material layer includes at least one of BaTiO₃, Pb(ZrTi)O₃, PbMgO₃, PbNbO₃, PbTiO₃, SrNb₂O₅, BaNb₂O₅, BiFeO₃, YMnO₃, TbMnO3, and TbMn₂O₅.

16. The memory device of claim 12 wherein the multiferroic layer is closer to the substrate than the ferromagnetic layer

17. The memory device of claim 12 wherein the ferromagnetic layer is closer to the substrate than the ferromagnetic layer.

18. The memory device of claim 12 wherein the ferromagnetic layer has an in-plane magnetization orientation and the multiferroic layer has an in-plane magnetization orientation.

19. The memory device of claim 12 wherein the ferromagnetic layer has an out-of-plane magnetization orientation and the multiferroic layer has an out-of-plane magnetization orientation.
